(19) United States
(12) Patent Application Publication
(10) Pub. No.: US 2008/0079055 A1
(43) Pub. Date: Apr. 3, 2008

(54) Non-volatile memory device

(75) Inventor: Hee Sik Park, Chungcheongbuk-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/635,208

(22) Filed: Dec. 7, 2006

(30) Foreign Application Priority Data
Jun. 28, 2006 (KR) 2006-58753

(51) Int. Cl. H01L 29/76

(52) U.S. Cl. 257/314

(57) ABSTRACT

A non-volatile memory device including a semiconductor substrate, an insulating layer, a channel boosting capacitor and a plug. A plurality of memory cells connected in series between a source select line and a drain select line are formed in the semiconductor substrate. The insulating layer is formed on the semiconductor substrate. The channel boosting capacitor is formed on a predetermined region of the insulating layer. A lower electrode, a dielectric layer and an upper electrode are laminated on the channel boosting capacitor. The plug connects one of the lower electrode and the upper electrode of the channel boosting capacitor to the semiconductor substrate between the source select line and memory cells through the insulating layer.

### BACKGROUND OF THE INVENTION

The invention relates, in general, to a non-volatile memory device and, more particularly, to a non-volatile memory device with an improved disturbance characteristic.

A semiconductor memory device can be largely classified into RAM (Random Access Memory) products, such as Dynamic RAM (DRAM) and Static RAM (SRAM), which have a volatile property wherein data are lost as time elapses and are fast in data I/O, and ROM (Read Only Memory) products that retain data once the data are input, but are slow in data I/O.

Of the ROM products, there is an increasing demand for non-volatile memory that allows for electrical I/O of data. The non-volatile memory device is a device that can be electrically erased at high speed while circuits are not removed from a board. The non-volatile memory device is advantageous in that the manufacturing cost per memory is low since the memory cell structure is simple and the refresh function of retaining data is unnecessary.

Non-volatile memory is largely classified into NOR non-volatile memory and NAND non-volatile memory. The NOR non-volatile memory requires one contact per two cells. The NOR non-volatile memory is disadvantageous in a high level of integration, but is advantageous in high speed since the cell current is high. The NAND non-volatile memory is disadvantageous in high speed since the cell current is low, but is advantageous in a high level of integration since a plurality of cells share one contact. Accordingly, the NAND non-volatile memory has been widely used in MP3 players, digital cameras, mobile products, assistant storage devices, and so on and, therefore, has been in the spotlight as the next-generation memory.

A cross section and equivalent circuit diagram of a general NAND non-volatile memory cell array are shown in FIGS. 1 and 2.

In the NAND non-volatile memory cell array shown in FIGS. 1 and 2, memory cells MC0 . . . MC15, each of which has a gate of a structure in which a floating gate 18 and a control gate 22 are laminated between a drain select line DST for selecting a unit string and a source select line SST for selecting ground are connected in series to form one string.

A plurality of the strings are connected in parallel in bit lines B/L1, B/L2, . . . to form one block. The blocks are disposed symmetrically around the bit line contact. The select transistors DST and SST and the memory cells MC0, . . . , MC15 are arranged in matrix form. Gates of the drain select line DST and the source select line SST arranged on the same column are connected to a drain select line DSL and a source select line SSL, respectively.

Furthermore, the memory cells MC0 . . . MC15 arranged on the same column have gates connected to a plurality of corresponding word lines WL0 . . . WL15. In addition, the drain select line DST has a drain connected to the bit line B/L, and the source select line SST has a source connected to the common source line Common CSL.

Each of the gates of the memory cells MC0, . . . MC15 has a structure in which the floating gate 18 formed over the semiconductor substrate 10 with an intervening tunnel oxide layer 16 disposed therebetween, and the control gate 22 formed over the floating gate 18 with an intervening dielectric layer 20 disposed therebetween are laminated. The floating gate 18 is formed to extend over the active region and a portion of the edge of the field region at both sides of the active region, thereby being separated from the floating gate 18 of a neighboring memory cell. The control gate 22 is connected to the control gate 22 of a neighboring memory cell, including the floating gate 18 independently formed with the field region therebetween, thus forming a word line.

The select transistors DST and SST are transistors not requiring the floating gate for storing data therein. Accordingly, the floating gate 18 and the control gate 22 are connected by a metal line through abutting contact on the field region within the cell array. Therefore, the select transistors DST and SST operate as a MOS transistor having a one-layer gate electrically.

A program operation of the NAND non-volatile memory device constructed above will be described below.

In the program operation, a voltage of 0 V is applied to a selected bit line and a program voltage Vpgm is applied to a selected word line. Accordingly, the electrons of the channel region are injected into the floating gate by Fowler-Nordheim (F-N) tunneling due to a high voltage difference between the channel region and the control gate of a selected memory cell. In this case, an unselected word line is applied with a pass voltage Vpass for transferring data 0V applied to a selected bit line to a selected memory cell.

However, the program voltage Vpgm is applied to not only a selected memory cell, but also unselected memory cells arranged along the same word line, so that unselected memory cells connected to the same word line are programmed. This phenomenon is called “program disturbance”.

To prevent such program disturbance, the source of the drain select line DST of a string including an unselected memory cell connected to a selected word line and an unselected bit line is charged to Vcc-Vth (Vcc is the power supply voltage and Vth is the threshold voltage of the drain select line) level. Thereafter, the selected word line is applied with the program voltage Vpgm and the unselected word line is applied with the pass voltage Vpass, thereby boosting the channel voltage Vch of memory cells belonging to the same string. Accordingly, unselected memory cells can be prevented from being programmed.

However, disturbance is generated due to a difference between the voltage of 0 V applied to the gate of the source select line SST and a voltage between channels boosted to a high level. Such a phenomenon will be described in more detail with reference to FIG. 3.

FIG. 3 is a view illustrating the disturbance phenomenon generated due to channel boosting.

If the channel voltage Vch is boosted to a high level in order to prevent program, a strong electric field (E-field) is generated in the junction overlap region of the source select line SST due to a difference between the voltage of 0 V applied to the gate of the source select line SST and a voltage between channels boosted to a high level. Hot carriers are generated by the E-field. Holes of the hot carriers are moved toward the substrate under the influence of the substrate bias, and electrons of the hot carriers are moved into the string by an electric field.

Meanwhile, a strong vertical E-field is formed in the direction of the floating gate 18 of an unselected memory cell (i.e., MC0) by a program voltage of 16 V to 18 V applied through WL0. Electrons moved into the string under the influence of the vertical E-field are injected into the floating gate 18 of MC0, generating disturbance.

FIG. 4 is a graph showing a disturbance characteristic of a memory cell transistor MC0 adjacent to a source select line SST. FIG. 5 is a graph showing a disturbance characteristic of the remaining memory cell transistors other than the transistor MC0.

From FIGS. 4 and 5, it can be seen that a disturbance characteristic of the memory cell MC0 is further aggravated compared with other memory cells. The degradation of the disturbance characteristic of the memory cell MC0 adjacent to the source select line SST becomes more profound as devices become smaller in size. As a result, it limits a characteristic and reliability of a device.

### SUMMARY OF THE INVENTION

Accordingly, the invention addresses the above problems, and discloses a non-volatile memory device wherein the disturbance characteristic can be improved.

A non-volatile memory device according to a first aspect of the present invention includes a plurality of memory cells over semiconductor substrate including a source select line, a drain select line and word lines, an insulating layer formed on the memory cells, a channel boosting capacitor formed on the word lines region of the insulating layer, wherein the channel boosting capacitor is formed on a lower electrode, a dielectric layer and a upper electrode, and a plug for connecting the upper electrode of the channel boosting capacitor to the semiconductor substrate between the source select line and the word line through the insulating layer.

A non-volatile memory device according to a second aspect of the invention includes a plurality of memory cells over a semiconductor substrate including a source select line, a drain select line and word lines, an insulating layer formed on the memory cells, a channel boosting capacitor formed on the word lines region of the insulating layer, wherein the channel boosting capacitor is formed on a lower electrode, a dielectric layer and an upper electrode, and a plug for connecting the upper electrode of the channel boosting capacitor to the semiconductor substrate between the drain select line and word line through the insulating layer.

The plug may preferably be formed using polysilicon.

A non-volatile memory device according to a third aspect of the invention includes a plurality of memory cells over a semiconductor substrate including a source select line, a drain select line and word lines, an insulating layer formed on the memory cells, a channel boosting capacitor formed on the word lines region of the insulating layer, wherein the channel boosting capacitor is formed on a lower electrode, a dielectric layer and an upper electrode, a first plug for connecting the upper electrode of the channel boosting capacitor to the semiconductor substrate between the source select line and the word line through the insulating layer, and a second plug for connecting the upper electrode of the channel boosting capacitor to the semiconductor substrate between the drain select line and the word line through the insulating layer.

The lower electrode of the channel boosting capacitor is connected to a ground terminal.

The insulating layer may preferably be formed using an oxide layer or a nitride layer. The lower electrode and the upper electrode may preferably be formed using polysilicon. The first and second plugs may preferably be formed using polysilicon.

### BRIEF DESCRIPTION OF THE DRAWINGS

FIG. 1 is a cross-sectional view showing a vertical structure of a general NAND non-volatile memory cell array;

FIG. 2 is an equivalent circuit diagram of the NAND flash cell array shown in FIG. 1;

FIG. 3 is a view illustrating the state of a string connected to a selected word line1 W/L1 and a unselected bit line;

FIG. 4 is a graph showing a disturbance characteristic of a memory cell transistor MC0 adjacent to a source select line SST;

FIG. 5 is a graph showing a disturbance characteristic of the remaining memory cell transistors other than the transistor MC0;

FIG. 6 is a plan view of a non-volatile memory device according to a first embodiment of the invention;

FIG. 7 is a cross-sectional view of the non-volatile memory device taken along line A-A in FIG. 6;

FIG. 8 is a plan view of a non-volatile memory device according to a second embodiment of invention;

FIG. 9 is a cross-sectional view of the non-volatile memory device taken along line B-B in FIG. 8;

FIG. 10 is a plan view of a non-volatile memory device according to a third embodiment of the invention;

FIG. 11 is a cross-sectional view of the non-volatile memory device taken along line C-C in FIG. 10; and

FIG. 12 is an equivalent circuit diagram of a non-volatile memory device according to the invention.

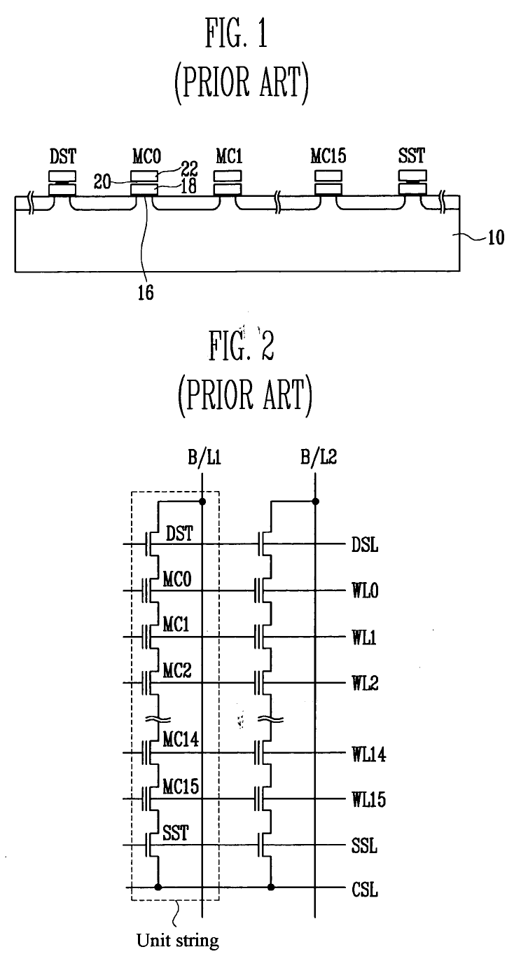

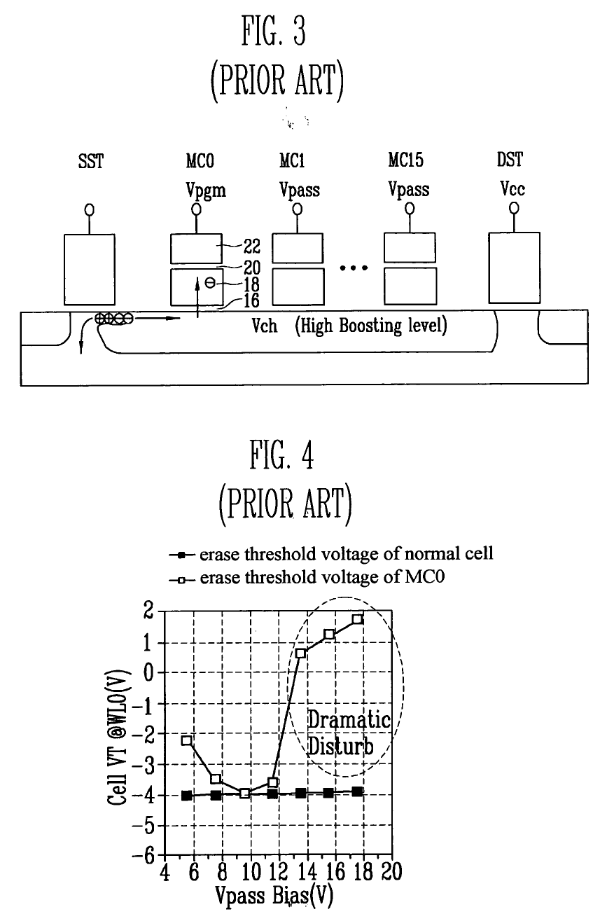

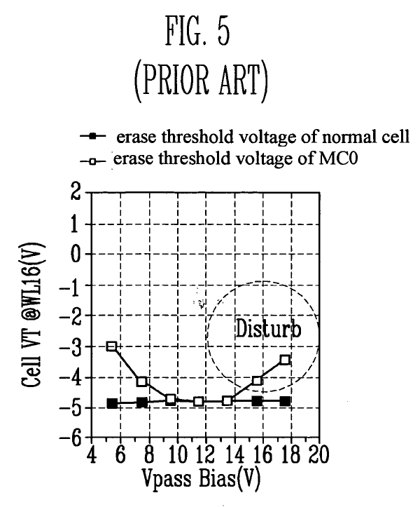

### DESCRIPTION OF THE SPECIFIC EMBODIMENTS

Specific embodiments of the invention will be described with reference to the accompanying drawings.

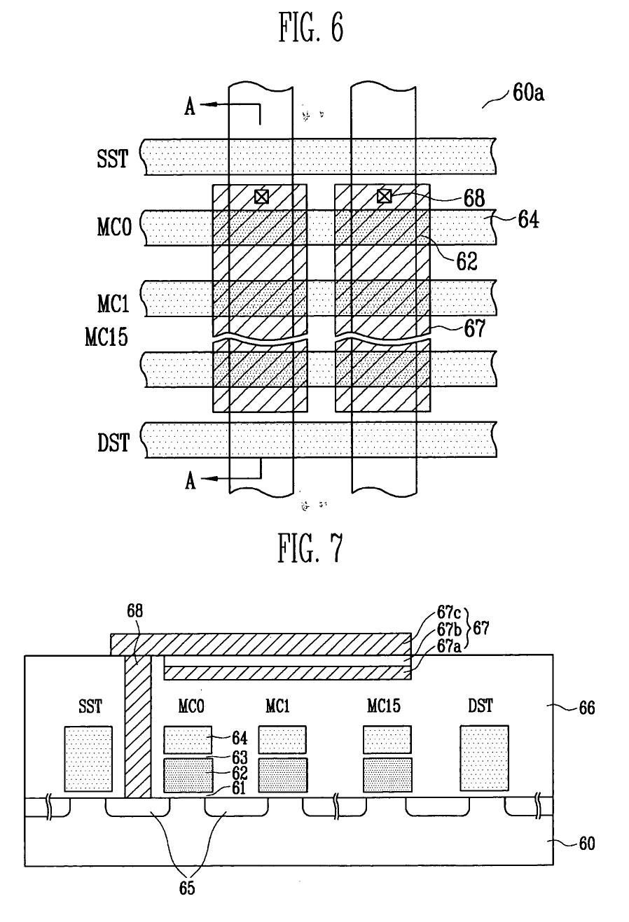

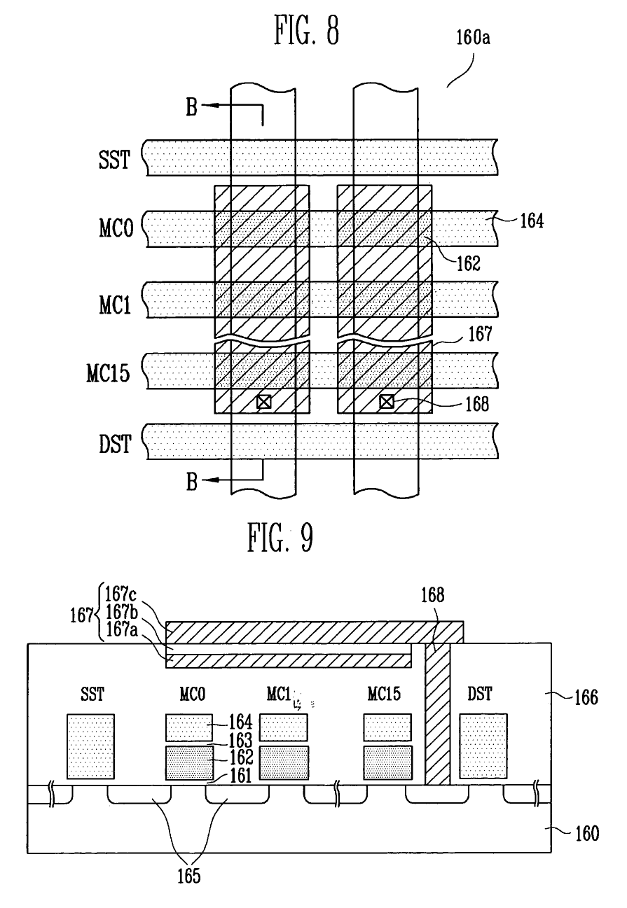

FIG. 6 is a plan view of a non-volatile memory device according to a first embodiment of the invention. FIG. 7 is a cross-sectional view of the non-volatile memory device taken along line A-A in FIG. 6.

Referring to FIGS. 6 and 7, a drain select line DST, memory cells MC0 . . . MC15, and a source select line SST are connected in series to form a unit string in a semiconductor substrate 60 having an active region defined by an isolation structure 60a. A channel boosting capacitor 67 is formed on the semiconductor substrate 60 including the drain select line DST, and the memory cells MC0 . . . MC15 and the source select line SST.

The channel boosting capacitor 67 is formed over the active region and over a portion of the edge of the isolation structure 60a at both sides of the active region in line form. One channel boosting capacitor 67 is formed in every unit string. The channel boosting capacitor 67 includes a lower electrode 67a, a dielectric layer 67b and an upper electrode 67c, all of which are laminated. The channel boosting capacitor 67 is insulated from the underlying drain select line DST, memory cells MC0 . . . MC15 and source select line SST with an insulating layer 66 therebetween.

The upper electrode 67c of the channel boosting capacitor 67 is connected to the semiconductor substrate 60 between the source select line SST and an adjacent memory cell (i.e., MC0) through a plug 68 formed in the insulating layer 66. Furthermore, the lower electrode 67a of the channel boosting capacitor 67 is connected to a ground terminal (not shown). The lower electrode 67a and the upper electrode 67c of the channel boosting capacitor 67, and the plug 68 may be formed using a polysilicon layer, and the insulating layer 66 may be formed using a nitride layer or oxide layer, for example.

A gate of each of the memory cells MC0 . . . MC15 has a structure in which a floating gate 62 formed over the semiconductor substrate 60 with an intervening tunnel oxide layer 61 disposed therebetween, and a control gate 64 formed over the floating gate 62 with an intervening dielectric layer 63 disposed therebetween are laminated.

The floating gate 62 is formed over the active region and a portion of the edge of the isolation structure 60a at both sides of the active region, and is, therefore, separated from the floating gate 62 of a neighboring memory cell. The control gate 64 is connected to the floating gate 62 that is independently with the field region intervened therebetween and the control gate 64 of a neighboring memory cell, thereby forming a word line.

The select transistors DST and SST are transistors not requiring a floating gate for storing data. The floating gate 62 and the control gate 64 are connected using a metal line through abutting contact on the field region within the cell array.

Accordingly, the select transistors DST and SST operate as a MOS transistor having a one-layer gate electrically. Reference numeral 65 indicates a junction region formed by impurity ion implantation.

The above semiconductor memory device according to the first embodiment includes the channel boosting capacitor 67 connected to the semiconductor substrate 60 between the source select line SST and the memory cell MC0 in order to extend an electrical distance between the source select line SST and MC0. It is therefore possible to reduce the number of hot carriers injected into the floating gate of the memory cell MC0. It results in an improved disturbance characteristic of the memory cell MC0.

Furthermore, the channel boosting voltage level can be raised by the channel boosting capacitor 67, which will be described in detail below. It is therefore possible to improve a disturbance characteristic of all the memory cells within a corresponding string.

FIG. 8 is a plan view of a non-volatile memory device according to a second embodiment of the invention. FIG. 9 is a cross-sectional view of the non-volatile memory device taken along line B-B in FIG. 8.

The construction of the non-volatile memory device according to the second embodiment is the same as those of the first embodiment except that the upper electrode 67c of the channel boosting capacitor 67 is connected to the semiconductor substrate 60 between the drain select line DST and an adjacent memory cell MC15.

Referring to FIGS. 8 and 9, a drain select line DST, memory cells MC0 . . . MC15, and a source select line SST are connected in series to form a unit string in a semiconductor substrate 160 having an active region defined by an isolation structure 160a. A channel boosting capacitor 167 is formed on the semiconductor substrate 160 including the drain select line DST, and the memory cells MC0 . . . MC15 and the source select line SST.

The channel boosting capacitor 167 is formed over the active region and over a portion of the edge of the isolation structure 160a at both sides of the active region in line form. One channel boosting capacitor 167 is formed every unit string.

The channel boosting capacitor 167 includes a lower electrode 167a, a dielectric layer 167b and an upper electrode 167c, all of which are laminated. The channel boosting capacitor 167 is insulated from the underlying drain select line DST, memory cells MC0 . . . MC15 and source select line SST with an insulating layer 166 disposed therebetween.

The upper electrode 167c of the channel boosting capacitor 167 is connected to the semiconductor substrate 160 between the source select line SST and the memory cell MC15 through a plug 168 formed in the insulating layer 166. Furthermore, the lower electrode 167a of the channel boosting capacitor 167 is connected to a ground terminal (not shown). The lower electrode 167a and the upper electrode 167c of the channel boosting capacitor 167, and the plug 168 may be formed using a polysilicon layer, and the insulating layer 166 may be formed using a nitride layer or oxide layer.

A gate of each of the memory cells MC0 . . . MC15 has a structure in which a floating gate 162 formed over the semiconductor substrate 160 with an intervening tunnel oxide layer 161 disposed therebetween, and a control gate 164 formed over the floating gate 162 with an intervening dielectric layer 163 disposed therebetween are laminated.

The floating gate 162 is formed over the active region and a portion of the edge of the isolation structure 160a at both sides of the active region and, therefore, is separated from the floating gate 162 of a neighboring memory cell. The control gate 164 is connected to the floating gate 162 that is independently with the intervening field region disposed therebetween and the control gate 164 of a neighboring memory cell, thereby forming a word line.

The select transistors DST and SST are transistors not requiring a floating gate for storing data. The floating gate 162 and the control gate 164 are connected using a metal line through abutting contact on the field region within the cell array.

Accordingly, the select transistors DST and SST operate as a MOS transistor having a one-layer gate electrically. Reference numeral 65 indicates a junction region formed by impurity ion implantation.

The above semiconductor memory device according to the second embodiment includes the channel boosting capacitor 167 connected to the semiconductor substrate 160 between the drain select line DST and the memory cell MC15 in order to extend an electrical distance between the drain select line DST and MC15. It is therefore possible to reduce the number of hot carriers injected into the floating gate of the memory cell MC15. Accordingly, a disturbance characteristic of the memory cell MC15 can be improved.

Furthermore, the channel boosting voltage level can be raised by the channel boosting capacitor 167, which will be described in detail below. It is therefore possible to improve a disturbance characteristic of all the memory cells within a corresponding string.

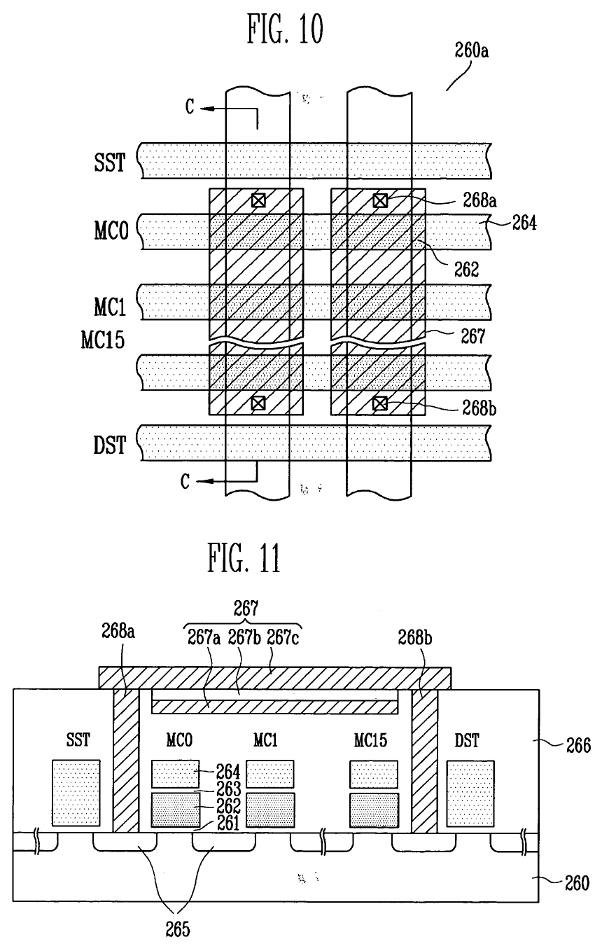

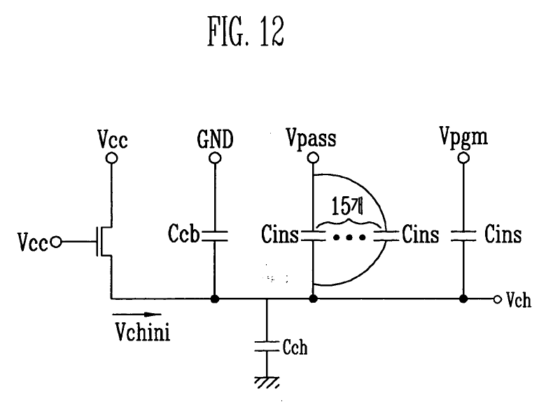

FIG. 10 is a plan view of a non-volatile memory device according to a third embodiment of the invention. FIG. 11 is a cross-sectional view of the non-volatile memory device taken along line C-C in FIG. 10.

The construction of the non-volatile memory device according to the third embodiment is the same as those of the first embodiment except that the upper electrode 267c of the channel boosting capacitor 267 is connected to the semiconductor substrate 260 between the source select line SST and the memory cell MC0 and the semiconductor substrate 260 between the drain select line DST and the memory cell MC15.

Referring to FIGS. 10 and 11, a drain select line DST, memory cells MC0 . . . MC15, and a source select line SST are connected in series to form a unit string in a semiconductor substrate 260 having an active region defined by an isolation structure 260a. A channel boosting capacitor 267 is formed on the semiconductor substrate 260 including the drain select line DST, and the memory cells MC0 . . . MC15 and the source select line SST.

The channel boosting capacitor 267 is formed over the active region and over a portion of the edge of the isolation structure 260a at both sides of the active region in line form. One channel boosting capacitor 267 is formed every unit string.

The channel boosting capacitor 267 includes a lower electrode 267a, a dielectric layer 267b and an upper electrode 267c, all of which are laminated. The channel boosting capacitor 267 is insulated from the underlying drain select line DST, memory cells MC0 . . . MC15 and source select line SST with an insulating layer 266 therebetween. The upper electrode 267c of the channel boosting capacitor 267 is connected to the semiconductor substrate 260 between the source select line SST and the memory cell MC0 and the semiconductor substrate 260 between the drain select line DST and the memory cell MC15 through a first plug 268a and a second plug 268b, respectively, which are formed in the insulating layer 266.

Furthermore, the lower electrode 267a of the channel boosting capacitor 267 is connected to a ground terminal (not shown). The lower electrode 267a and the upper electrode 267c of the channel boosting capacitor 267, the first plug 68a and the second plug 268b may preferably be formed using a polysilicon layer, and the insulating layer 266 may be formed using a nitride layer or oxide layer, for example.

A gate of each of the memory cells MC0, . . . , MC15 has a structure in which a floating gate 262 formed over the semiconductor substrate 260 with an intervening tunnel oxide layer 261 disposed therebetween, and a control gate 264 formed over the floating gate 262 with an intervening dielectric layer 263 disposed therebetween are laminated. The floating gate 262 is formed over the active region and a portion of the edge of the isolation structure 260a at both sides of the active region and, therefore, is separated from the floating gate 262 of a neighboring memory cell. The control gate 264 is connected to the floating gate 262 that is independently with the field region disposed therebetween and the control gate 64 of a neighboring memory cell, thereby forming a word line.

The select transistors DST and SST are transistors not requiring a floating gate for storing data. The floating gate 262 and the control gate 264 are connected using a metal line through a butting contact on the field region within the cell array. Accordingly, the select transistors DST and SST operate as a MOS transistor having a one-layer gate electrically. Reference numeral 265 indicates a junction region formed by impurity ion implantation.

The above semiconductor memory device according to the third embodiment includes the channel boosting capacitor 267 connected to the semiconductor substrate 260 between the source select line SST and the memory cell MC0 and the semiconductor substrate 260 between the drain select line DST and the memory cell MC15 in order to extend an electrical distance between the source select line SST and MC0 and the drain select line DST and MC15. It is therefore possible to reduce the number of hot carriers injected into the floating gate of the memory cells MC0 and MC15. Accordingly, a disturbance characteristic of the memory cells MC0 and MC15 can be improved.

Furthermore, the channel boosting voltage level can be raised by the channel boosting capacitor 267, which will be described in detail below. It is therefore possible to improve a disturbance characteristic of all the memory cells within a corresponding string.

An equivalent circuit of the non-volatile memory device constructed above is shown in FIG. 12.

FIG. 12 is an equivalent circuit diagram of a non-volatile memory device according to the invention. In FIG. 12, Cch indicates depletion capacitance generated by the depletion region formed below the channel, Cins indicates capacitance between the control gate of the memory cell and the channel, Ccb indicates capacitance of the channel boosting capacitor 67, 167 or 267. As shown in FIG. 12, Ccb and 16 Cins are connected in parallel.

To prevent program disturbance, a voltage of Vcc is applied to the drain and gate of the drain select line DST through a bit line. The program voltage Vpgm is applied to a selected word line, and the pass voltage Vpass is applied to unselected word lines.

Accordingly, the source of the drain select line DST is charged to the Vcc-Vth (Vcc is the power supply voltage and Vth is the threshold voltage of the drain select line) (hereinafter referred to as “Vchini”) level.

Assuming that a channel boosting ratio is Cr, the channel voltage Vch can be expressed in the following equation.

Vch=Vchini+Cr(Vpass-Vchini-Vth)+1/15 Cr(Vpgm-Vchini-Vth′)

$$Cr = \frac{15 Cins + Ceb}{16 Cins + Cch + Ccb}$$

where Vth is the threshold voltage of a memory cell connected to an unselected word line, and Vth′ is the threshold voltage of a memory cell connected to a selected word line.

The equation tells that the value Cr increases by Ccb of the channel boosting capacitor 67, 167, or 267, and consequently the channel voltage Vch is increased.

In the above embodiments, an example in which the upper electrode 67c, 167c, or 267c of the channel boosting capacitor 67, 167, or 267 is connected to the semiconductor substrate 60, 160, or 260 and the lower electrode 67a, 167a, or 267a of the channel boosting capacitor 67, 167, or 267 is connected to the ground terminal has been described. However, the lower electrode 67a, 167a, or 267a may be connected to the semiconductor substrate 60, 160, or 260 and the upper electrode 67c, 167c, or 267c may be connected to the ground terminal.

Furthermore, in the above embodiments, an example in which the unit string includes 16 memory cells has been described. However, the unit string may include 16 memory cells or more (or less).

As described above, the invention has the following advantages.

The channel boosting capacitor is connected to the semiconductor substrate between the source select line and a memory cell or/and the drain select line and a memory cell in order to extend an electrical distance between the source select line and the memory cell. It is therefore possible to improve a disturbance characteristic of the device.

Furthermore, the channel boosting ratio and the channel boosting voltage can be increased by the channel boosting capacitor. It is therefore possible to improve a disturbance characteristic of memory cells.

Although the foregoing description has been made with reference to the various embodiments, changes and modifications may be made by those skilled in the art without departing from the spirit and scope of the invention.

What is claimed is:

1. A non-volatile memory device, comprising:
a plurality of memory cells over semiconductor substrate including a source select line, a drain select line and word lines;
an insulating layer formed on the memory cells;
a channel boosting capacitor formed on the word lines region of the insulating layer, wherein the channel boosting capacitor is formed on a lower electrode, a dielectric layer and a upper electrode; and
a plug for connecting the upper electrode of the channel boosting capacitor to the semiconductor substrate between the source select line and the word line through the insulating layer.

2. The non-volatile memory device of claim 1, wherein the lower electrode of the channel boosting capacitor is connected to a ground terminal.

3. The non-volatile memory device of claim 1, wherein the insulating layer comprises an oxide layer or a nitride layer.

4. The non-volatile memory device of claim 1, wherein the lower electrode and the upper electrode comprise polysilicon.

5. The non-volatile memory device of claim 1, wherein the plug comprises polysilicon.

6. A non-volatile memory device, comprising:
a plurality of memory cells over a semiconductor substrate including a source select line, a drain select line and word lines;
an insulating layer formed on the memory cells;
a channel boosting capacitor formed on the word lines region of the insulating layer, wherein the channel boosting capacitor is formed on a lower electrode, a dielectric layer and an upper electrode; and
a plug for connecting the upper electrode of the channel boosting capacitor to the semiconductor substrate between the drain select line and word line through the insulating layer.

7. The non-volatile memory device of claim 6, wherein the lower electrode of the channel boosting capacitor is connected to a ground terminal.

8. The non-volatile memory device of claim 6, wherein the insulating layer comprise an oxide layer or a nitride layer.

9. The non-volatile memory device of claim 6, wherein the lower electrode and the upper electrode comprises polysilicon.

10. The non-volatile memory device of claim 6, wherein the plug comprises polysilicon.

11. A non-volatile memory device, comprising:
a plurality of memory cells over a semiconductor substrate including a source select line, a drain select line and word lines;
an insulating layer formed on the memory cells;
a channel boosting capacitor formed on the word lines region of the insulating layer, wherein the channel boosting capacitor is formed on a lower electrode, a dielectric layer and an upper electrode;
a first plug for connecting the upper electrode of the channel boosting capacitor to the semiconductor substrate between the source select line and the word line through the insulating layer; and
a second plug for connecting the upper electrode of the channel boosting capacitor to the semiconductor substrate between the drain select line and the word line through the insulating layer.

12. The non-volatile memory device of claim 11, wherein the lower electrode of the channel boosting capacitor is connected to a ground terminal.

13. The non-volatile memory device of claim 11, wherein the insulating layer comprises an oxide layer or a nitride layer.

14. The non-volatile memory device of claim 11, wherein the lower electrode and the upper electrode comprises polysilicon.

15. The non-volatile memory device of claim 11, wherein the first plug and the second plug comprises polysilicon.
